(19) United States
(12) Patent Application Publication
(10) Pub. No.: US 2026/0363347 A1
(43) Pub. Date: Nov. 19, 2026

(54) POWER SUPPLY UNIT FOR AEROSOL-GENERATING DEVICE, AND AEROSOL-GENERATING DEVICE

(71) Applicant: Japan Tobacco Inc., Tokyo (JP)

(72) Inventors: Junji MINATO, Tokyo (JP); Hiroshi KAWANAGO, Tokyo (JP)

(73) Assignee: Japan Tobacco Inc., Tokyo (JP)

(21) Appl. No.: 19/138,674

(22) PCT Filed: Dec. 16, 2022
(86) PCT No.: PCT/JP2022/046476

§ 371 Date: Jun. 13, 2025

(51) Int. Cl. A24F 40/57; A24F 40/40; H01M 50/247; H01M 50/583; H05B 1/02

(52) U.S. Cl. CPC A24F 40/57; A24F 40/40; H01M 50/247; H01M 50/583; H05B 1/0252; H01M 2200/103; H01M 2220/30

(57) ABSTRACT

This inhalation device comprises a power supply part that supplies power to a heating unit, a main board, and a power supply board. The power supply board is provided with a positive electrode tab connection that is connected to a positive electrode tab, a positive contact connection part that is connected to a contact of the main board, and a first positive electroconductive region and a second positive electroconductive region that connect the positive electrode tab connection part and the positive contact connection part. The widths of the first positive electroconductive region and the second positive electroconductive region are both greater than the width of the positive electrode tab connection part.

### TECHNICAL FIELD

The present disclosure relates to a power supply unit for an aerosol-generating device, and an aerosol generating-device.

### BACKGROUND ART

This aerosol-generating device accommodates, within a case, a power supply, a heating unit, a plurality of sensors, a circuit board for mounting the sensors or a control device, etc. (e.g., PTL 1). An aerosol-generating device, such as a heating smoking device, is preferably sized to fit in the hand of the user.

### CITATION LIST

### Patent Literature

[PTL 1] Japanese Patent Application Publication No. 2021-83383 A1

### SUMMARY OF INVENTION

### Technical Problem

In an aerosol-generating device, the aerosol source is heated rapidly, and thus the current supplied from the power supply is high for a small device. Therefore, it is necessary to ensure that power can be properly supplied to the heating unit.

The present disclosure provides a power supply unit of an aerosol-generating device that can suitably perform power supply, and an aerosol-generating device.

### Solution to Problem

A power supply unit for an aerosol-generating device of the present disclosure comprises:
a power supply that supplies electrical power to a heating unit for heating an aerosol source;
a control device that controls the heating unit;
a first board for mounting the control device; and
a second board connected to the power supply and the first board, wherein
the second board includes
   an electrode connection part connected to an electrode of the power supply,
   a contact connection part connected to a contact of the first board, and
   an electroconductive region connecting the electrode connection part and the contact connection part, wherein
the width of the electroconductive region is wider than the width of the electrode connection part.

An aerosol-generating device of the present disclosure comprises:
a power supply;
a heating unit that consumes electrical power supplied from the power supply to heat an aerosol source;
a control device that controls the heating unit;
a first board for mounting the control device; and
a second board connected to the power supply and the first board, wherein
the second board includes
   an electrode connection part connected to an electrode of the power supply,
   a contact connection part connected to a contact of the first board, and
   an electroconductive region connecting the electrode connection part and the contact connection part, wherein
the width of the electroconductive region is wider than the width of the electrode connection part.

### Advantageous Effects of Invention

According to the present disclosure, due to the wide conductive region, current concentration within the second board can be avoided even if a large current flows from the power supply via the electrode connection, and power can be suitably supplied from the power supply.

### BRIEF DESCRIPTION OF DRAWINGS

FIG. 1 is a schematic diagram illustrating a first configuration example (inhalation device 100A) of an inhalation device.

FIG. 2 is a schematic diagram illustrating a second configuration example (inhalation device 100B) of the inhalation device.

FIG. 3 is an overall perspective view of an inhalation device 100 according to one embodiment of the present disclosure.

FIG. 4 is a perspective view seen from the front right side of an internal unit 10.

FIG. 5 is a perspective view seen from the front left side of the internal unit 10.

FIG. 6 is an exploded perspective view of the internal unit 10.

FIG. 7 is a cross-sectional perspective view of a heater assembly 30.

FIG. 8 is a block diagram that briefly illustrates the electrical connection of the main elements of the internal unit 10.

FIG. 9 is a cross-sectional view of a power supply board 71.

FIG. 10 is a view of a first conductive layer L1 and a second conductive layer L2 of the power supply board 71 seen from the front.

FIG. 11 is a view of the first conductive layer L1 and the second conductive layer L2 of the power supply board 71 of a variant example seen from the front.

FIG. 12 is a diagram illustrating an example of a positive electrode tab 111a connected to a positive electrode tab connection part 711a.

FIG. 13 is a diagram illustrating another example of the positive electrode tab 111a connected to the positive electrode tab connection part 711a.

### DESCRIPTION OF EMBODIMENTS

The following is an explanation of an inhalation device, control method, and program according to one embodiment of the present disclosure. First, two configuration examples (a first configuration example and a second configuration example) to which the configuration of the inhalation device according to the present disclosure can be applied are described. It should be noted that, hereinafter, the same or similar elements may be given the same or similar reference signs, and the description thereof may be omitted or simplified as appropriate.

### 1. CONFIGURATION EXAMPLE OF INHALATION DEVICE

An inhalation device is a device for generating a substance to be inhaled by a user. Hereinafter, the substance generated by the inhalation device is described as being an aerosol. Alternatively, the substance generated by the inhalation device may be a gas.

### (1) First Configuration Example

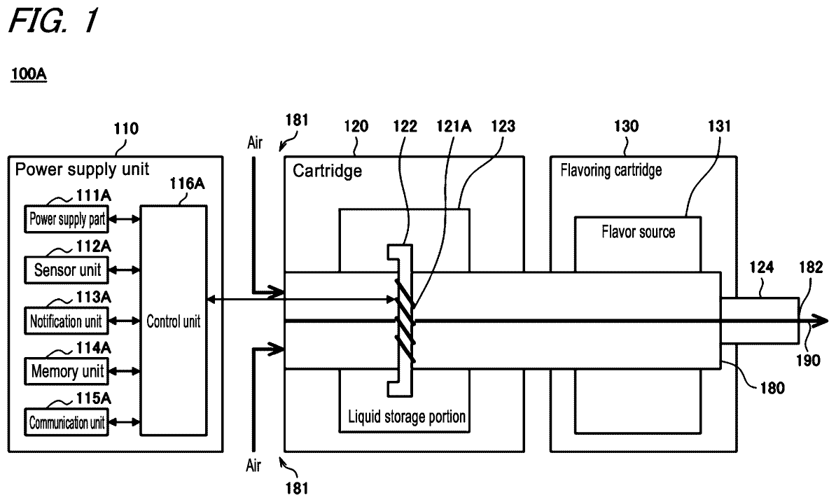

FIG. 1 is a schematic diagram illustrating a first configuration example of the inhalation device. As shown in FIG. 1, an inhalation device 100A according to the present configuration example includes a power supply unit 110, a cartridge 120, and a flavoring cartridge 130. The power supply unit 110 comprises a power supply part 111A, a sensor unit 112A, a notification unit 113A, a memory unit 114A, a communication unit 115A, and a control unit 116A. The cartridge 120 includes a heating unit 121A, a liquid guiding portion 122, and a liquid storage portion 123. The flavoring cartridge 130 includes a flavor source 131 and a mouthpiece 124. An air flow path 180 is formed in the cartridge 120 and the flavoring cartridge 130.

The power supply part 111A stores electrical power. The power supply part 111A then supplies the electrical power to each component of the inhalation device 100A in accordance with control performed by the control unit 116A. The power supply part 111A may be configured, for example, by a rechargeable battery such as a lithium ion secondary battery.

The sensor unit 112A acquires various types of information relating to the inhalation device 100A. As an example, the sensor unit 112A is configured from a pressure sensor such as a condenser microphone, a flow rate sensor or a temperature sensor, and so on, and acquires values associated with inhalation by a user. As another example, the sensor unit 112A is configured from an input device, such as a button or switch, for accepting input of information from the user.

The notification unit 113A notifies the user of information. The information that the notification unit 113A notifies to the user is various including, for example, an SOC (State of charge) indicating a state of charge of the power supply part 111A, pre-heating time at the time of inhalation, inhalation period, time that inhalation is possible, and so on. The notification unit 113A can be configured from, for example, a light-emitting device that emits light, a display device that displays images, a sound output device that outputs sound, a vibration device that vibrates, and so on.

The memory unit 114A stores various types of information for the operation of the inhalation device 100A. The memory unit 114A can be configured from a non-volatile storage medium such as a flash memory, for example.

The communication unit 115A is a communication interface capable of performing communication in accordance with any wired or wireless communication standard. Examples of communication standards that may be used include standards that employ Wi-Fi (registered trademark), Bluetooth (registered trademark), Bluetooth Low Energy (BLE) (registered trademark), Near-Field Communication (NFC), or Low Power Wide Area (LPWA), and so on.

The control unit 116A functions as an arithmetic processing device and a control device, and controls overall operation within the inhalation device 100A in accordance with various programs. The control unit 116A is realized by a central processing unit (CPU) or an electronic circuit such as a microprocessor, for example.

The liquid storage portion 123 stores an aerosol source. The aerosol source is atomized to generate an aerosol. The aerosol source is a polyhydric alcohol such as glycerol or propylene glycol, or a liquid such as water, for example. The aerosol source may include tobacco-derived or non-tobacco-derived flavor components. If the inhalation device 100A is a medical inhaler such as a nebulizer, the aerosol source may include a drug.

The liquid guiding portion 122 guides the aerosol source, which is the liquid stored in the liquid storage portion 123, from the liquid storage portion 123, and holds the aerosol source. The liquid guiding portion 122 is, for example, a wick formed by twisting a fibrous material such as glass fibers or a porous material such as a porous ceramic. In this case, the aerosol source stored in the liquid storage portion 123 is guided by the capillary effect of the wick.

The heating unit 121A heats the aerosol source to atomize the aerosol source, thereby generating the aerosol. In the example shown in FIG. 1, the heating unit 121A is configured as a coil wrapped around the liquid guiding portion 122. When the heating unit 121A generates heat, the aerosol source held in the liquid guiding portion 122 is then heated and atomized, generating the aerosol. The heating unit 121A generates heat when supplied with electricity from the power supply part 111A. For example, electricity may be supplied to the heating unit 121A when the sensor unit 112A detects that the user has started inhaling and/or that predetermined information has been input. The supply of electricity to the heating unit 121A may then be stopped when the sensor unit 112A detects that the user has finished inhaling and/or that predetermined information has been input. Note that the inhalation action of the user on the inhalation device 100A is detectable, for example, based on pressure (internal pressure) exceeding a predetermined threshold in the inhalation device 100A detected by an inhalation sensor.

The flavor source 131 is a component for imparting a flavor component to the aerosol. The flavor source 131 may include tobacco-derived or non-tobacco-derived flavor components.

The air flow path 180 is a flow path for air to be inhaled by the user. The air flow path 180 has a tubular structure with an air inflow hole 181, which is an inlet for air into the air flow path 180, and an air outflow hole 182, which is an outlet for air from the air flow path 180. Within the air flow path 180, the liquid guiding portion 122 is disposed upstream (closer to the air inflow hole 181), and the flavor source 131 is disposed downstream (closer to the air outflow hole 182). Air flowing in through the air inflow hole 181 upon inhalation by the user is mixed with the aerosol generated by the heating unit 121A and transported through the flavor source 131 to the air outflow hole 182, as shown by the arrow 190. When the mixed fluid of aerosol and air passes through the flavor source 131, the flavor component contained in the flavor source 131 is applied to the aerosol.

The mouthpiece 124 is a member that is held in the user's mouth during inhalation. The air outflow hole 182 is disposed in the mouthpiece 124. The user holds the mouthpiece 124 in their mouth to make it possible to draw the mixed fluid of aerosol and air into the oral cavity.

A configuration example of the inhalation device 100A has been described above. The inhalation device 100A is, of course, not limited to the configuration described above, and various configurations may be adopted, such as those illustrated below as examples.

As an example, the inhalation device 100A need not include the flavoring cartridge 130. In this case, the cartridge 120 is provided with the mouthpiece 124.

As another example, the inhalation device 100A may include a plurality of types of aerosol sources. Other types of aerosol may be generated by a plurality of types of aerosol generated from the plurality of types of aerosol sources being mixed in the air flow path 180 to cause a chemical reaction.

Furthermore, the means for atomizing the aerosol source is not limited to heating provided by the heating unit 121A. For example, the means for atomizing the aerosol source may be vibration atomization or induction heating.

### (2) Second Configuration Example

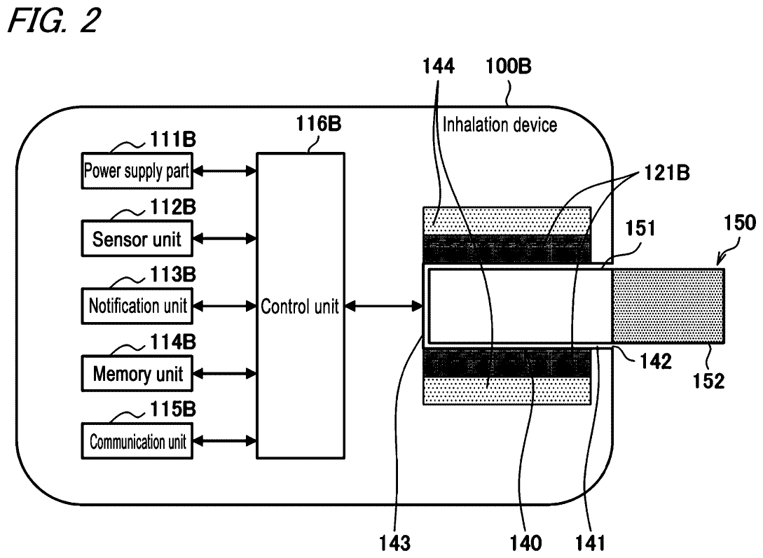

FIG. 2 is a schematic diagram illustrating a second configuration example of an inhalation device. As illustrated in FIG. 2, an inhalation device 100B according to the present configuration example comprises a power supply part 111B, a sensor unit 112B, a notification unit 113B, a memory unit 114B, a communication unit 115B, a control unit 116B, a heating unit 121B, an accommodating portion 140, and a heat insulating portion 144. While the inhalation device 100A of the first configuration example had the power supply unit 110 containing the power supply part 111A and the separate heating unit 121A, the inhalation device 100B of the second configuration example has an integral power supply part 111B and heating unit 121B. That is, the inhalation device 100B of the second configuration example can also be described as having a power supply unit with a built-in heating unit.

The power supply part 111B, sensor unit 112B, notification unit 113B, memory unit 114B, communication unit 115B, and control unit 116B are each substantially identical to the corresponding component included in the inhalation device 100A according to the first configuration example.

The accommodating portion 140 has an internal space 141, and holds a stick-type substrate 150 while accommodating a portion of the stick-type substrate 150 in the internal space 141. The accommodating portion 140 has an opening 142 allowing the internal space 141 to communicate with the outside, and accommodates the stick-type substrate 150 that has been inserted into the internal space 141 from the opening 142. For example, the accommodating portion 140 is a cylindrical body comprising the opening 142 and a bottom portion 143 serving as a bottom surface, and defines the columnar internal space 141. An air flow path for supplying air to the internal space 141 is connected to the accommodating portion 140. An air inflow hole, which is an inlet for air into the air flow path, is disposed in a side surface of the inhalation device 100, for example. An air outflow hole serving as an outlet for air from the air flow path to the internal space 141 is disposed in the bottom portion 143, for example.

The stick-type substrate 150 comprises a substrate portion 151 and a mouthpiece portion 152. The substrate portion 151 includes an aerosol source. The aerosol source includes a tobacco-derived or non-tobacco-derived flavor component. If the inhalation device 100B is a medical inhaler such as a nebulizer, the aerosol source may include a drug. The aerosol source may be, for example, a liquid such as water and polyhydric alcohols such as glycerol and propylene glycol comprising the tobacco-derived or non-tobacco-derived flavor component, or else may be a solid comprising the tobacco-derived or non-tobacco-derived flavor component. In a state in which the stick-type substrate 150 is being held in the accommodating portion 140, at least a portion of the substrate portion 151 is accommodated in the internal space 141, and at least a portion of the mouthpiece portion 152 protrudes from the opening 142. Then, when the user holds the mouthpiece portion 152 protruding from the opening 142 in their mouth and inhales, air flows into the internal space 141 via the air flow path, which is not illustrated in the drawings, and reaches the inside of the user's mouth together with the aerosol generated from the substrate portion 151.

In the example illustrated in FIG. 2, the heating unit 121B is configured in a film shape and is disposed so as to cover the outer periphery of the accommodating portion 140. Then, when the heating unit 121B generates heat, the substrate portion 151 of the stick-type substrate 150 is heated from the outer periphery, generating the aerosol.

The heat insulating portion 144 prevents heat transfer from the heating unit 121B to other components. For example, the heat insulating portion 144 is configured from a vacuum heat insulating material or an aerogel heat insulating material, or the like.

A configuration example of the inhalation device 100B has been described above. The inhalation device 100B is, of course, not limited to the configuration described above, and various configurations may be adopted, such as the examples illustrated below.

As one example, the heating unit 121B may have a blade-like form and may be arranged so as to protrude into the internal space 141 from the bottom portion 143 of the accommodating portion 140. In that case, the blade-like heating unit 121B is inserted into the substrate portion 151 of the stick-type substrate 150 and heats the substrate portion 151 of the stick-type substrate 150 from the inside. As another example, the heating unit 121B may be arranged so as to cover the bottom portion 143 of the accommodating portion 140. Furthermore, the heating unit 121B may be configured from a combination of two or more from among a first heating unit covering the outer circumference of the accommodating portion 140, a blade-like second heating unit, and a third heating unit covering the bottom portion 143 of the accommodating portion 140.

As another example, the accommodating portion 140 may comprise an opening/closing mechanism such as a hinge for opening/closing part of an external casing that forms the internal space 141. By opening/closing the casing, the accommodating portion 140 may then receive and grip the stick-type substrate 150 that has been inserted into the internal space 141. In this case, the heating unit 121B may be provided on the clamping part of the accommodating portion 140, and may heat the stick-type substrate 150 while pressing the same.

Furthermore, the means for atomizing the aerosol source is not limited to heating provided by the heating unit 121B. For example, the means for atomizing the aerosol source may be induction heating. In this case, the inhalation device 100B comprises at least an electromagnetic induction source such as a coil for generating a magnetic field, instead of the heating unit 121B. A susceptor which generates heat by means of induction heating may be provided in the inhalation device 100B, or may be contained in the stick-type substrate 150.

The inhalation device 100B may further include the heating unit 121A, the liquid guiding portion 122, the liquid storage portion 123 and the air flow path 180 according to the first configuration example, and the air flow path 180 may supply air to the internal space 141. In this case, the mixed fluid of aerosol and air generated by the heating unit 121A flows into the internal space 141 and is further mixed with the aerosol generated by the heating unit 121B to reach the oral cavity of the user.

### 2. CONFIGURATION EXAMPLES OF THE INHALATION DEVICE OF THE PRESENT DISCLOSURE

Next, an embodiment of the inhalation device (hereinafter referred to as the inhalation device 100) applying the configuration of the inhalation device of the present disclosure is described in relation to the inhalation device 100B of the second configuration example previously described. Note that although the specific description is omitted, some of the configuration of the inhalation device 100 elaborated below can also be applied to the inhalation device 100A of the first configuration example.

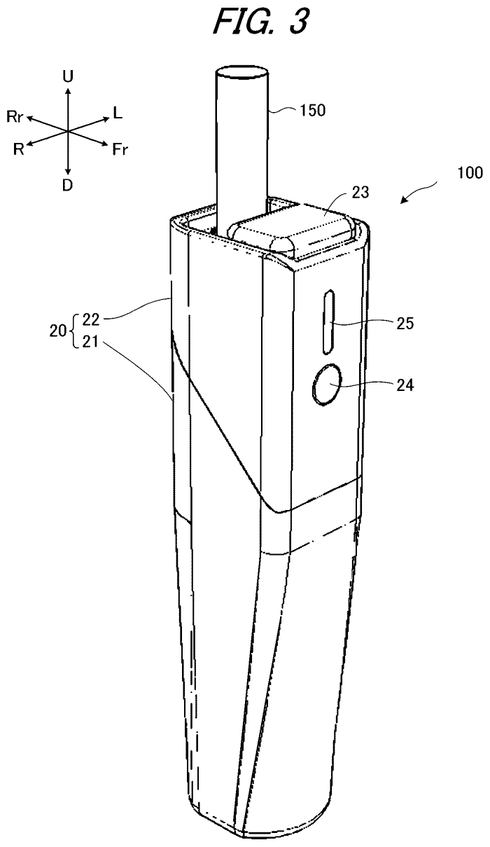

FIG. 3 is an overall perspective view of the inhalation device 100. In the following, in the inhalation device 100, the insertion and removal direction of the stick-type substrate 150 relative to the inhalation device 100 is defined as the vertical direction, the sliding movement direction of a shutter 23 described below is defined as the front-rear direction, and the direction perpendicular to the vertical direction and the front-rear direction is defined as the left-right direction. Also, as shown in the figures, Fr is the front, Rr is the rear, L is the left side, R is the right side, U is up, and D is down.

The inhalation device 100 is preferably sized to fit in the hand, for example, having a rod shape. For example, the user holds the inhalation device 100 in one hand, with fingertips in contact with the front surface of the inhalation device 100. Note that the shape of the inhalation device 100 is not limited to a rod shape, but can be any shape (for example, rounded substantially cuboid shape or ovoid shape).

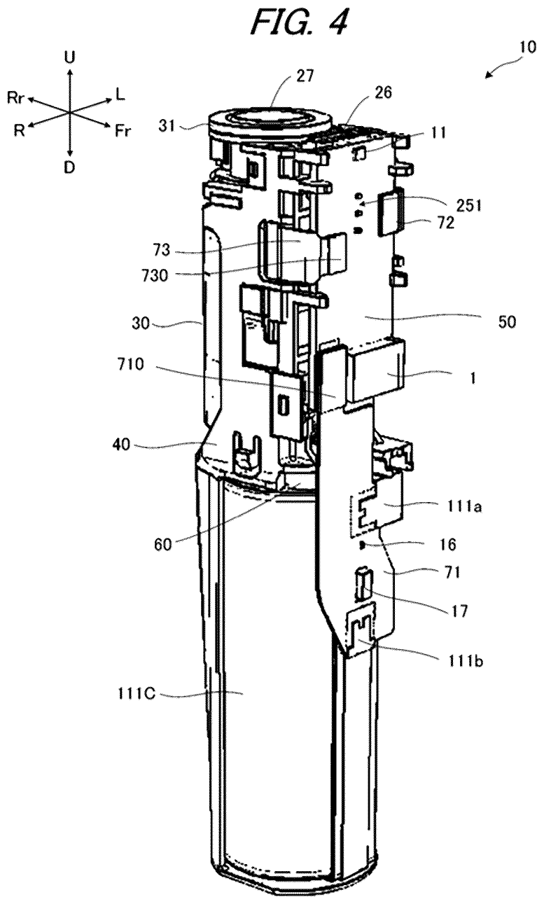

The inhalation device 100 comprises an internal unit 10 (see FIGS. 4 to 6), and a case 20 that constitutes the external appearance of the inhalation device 100. The case 20 has a lower case 21 and an upper case 22. A portion of the internal unit 10 is accommodated in the lower case 21, and the entire internal unit 10 is accommodated in the case 20 by covering the lower case 21 with the upper case 22 from above.

The upper surface of the inhalation device 100 is provided with an opening 27 (see FIGS. 4 to 6) through which the stick-type substrate 150 is inserted and removed, and a shutter 23 that is slidable in the front-rear direction. The opening 27 is arranged at the rear of the upper surface of the inhalation device 100. The shutter 23 selectively takes an open state (front position) in which the opening 27 is open to allow insertion and removal of the stick-type substrate 150, and a closed state (rear position) in which the shutter 23 is positioned above the opening 27 to obstruct the opening 27. When inserting the stick-type substrate 150 into the opening 27, the user places the shutter 23 in the open state.

In the vicinity of the shutter 23, a shutter detection sensor 11 (see FIG. 4) is provided. The shutter detection sensor 11 detects whether or not the shutter 23 is in the open state. The shutter detection sensor 11 is an example of the sensor unit 112B of the inhalation device 100B of FIG. 2.

Also, a Universal Serial Bus (USB) port 26 (see FIG. 4) is provided on the upper surface of the inhalation device 100 arranged adjacent to the opening 27. In the open state described above, the shutter 23 obstructs the USB port 26. On the other hand, in the closed state described above, the shutter 23 does not block the USB port 26 and the USB port 26 is open. The USB port 26 is configured to be electrically connectable with an external power supply (not shown on the drawings) capable of supplying power to charge a power supply part 111C (see FIG. 4). The USB port 26 is, for example, a receptacle in which a mating plug can be inserted. As an example, in the present embodiment, the USB port 26 is a USB Type-C receptacle.

An operation unit 24 and a light emitting unit 25 are provided on the front side of the inhalation device 100. The operation unit 24 is arranged below the light-emitting unit 25. In more detail, the operation unit 24 and the light-emitting unit 25 are one component of the internal unit 10 housed in the case 20, and are configured so that a part of the operation unit 24 and the light-emitting unit 25 are exposed through an opening formed in the front face of the case 20. The light emitting unit 25 is an example of the notification unit 113A of the inhalation device 100B of FIG. 2.

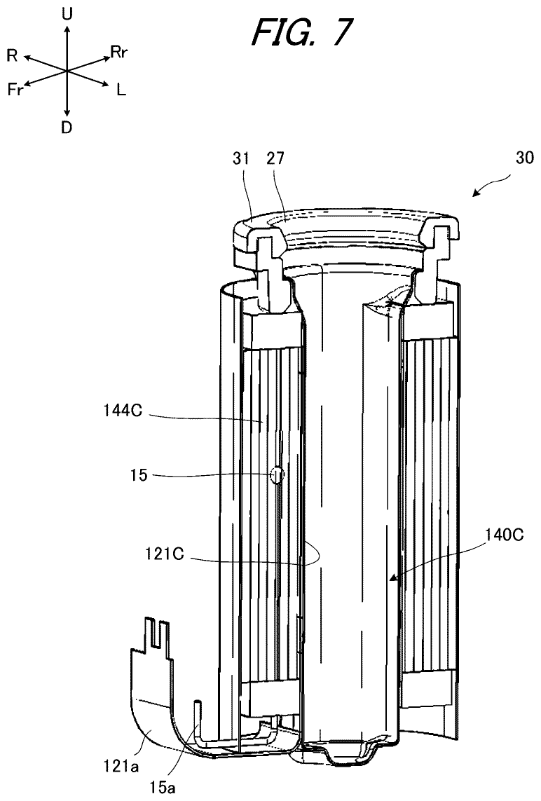

The operation unit 24 is a button-type switch that can be operated by a user, and is an input device for receiving input of information from a user. The operation unit 24 is connected to a main board 50 (see FIGS. 4 to 6) that is described later. The user depressing the operation unit 24, for example, activates a Micro Controller Unit (MCU) 1 (see FIGS. 4 to 6) or a heating unit 121C (see FIG. 7). Note that the MCU 1 acts as the control unit 116B in the inhalation device 100B. Also, the MCU 1 may be integrally provided with the functions of the communication unit 115B in addition to the functions of the control unit 116B in the inhalation device 100B. Furthermore, the MCU 1 may be configured from one IC, or may be configured from two or more ICs. For example, discharge control for the heating unit 121C and charging control to the power supply part 111C may be performed in one IC or may be performed in separate ICs.

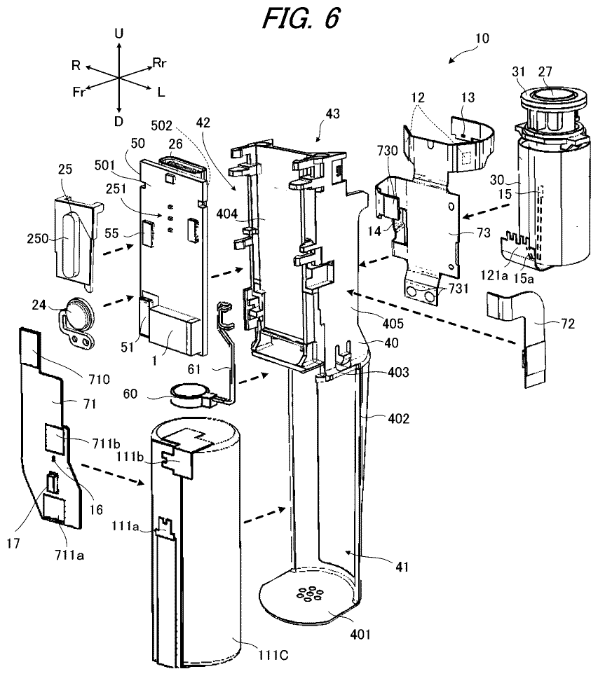

The light emitting unit 25 is configured from a light-emitting device such as, for example, a light-emitting diode (LED). In more detail, the light emitting unit 25 includes a plurality of LEDs 251 (see FIG. 6) provided on the main board 50, and a transparent cover 250 covering the plurality of LEDs 251 and allowing the transmission of light from the LEDs 251. A portion of the transparent cover 250 is exposed through an opening formed in the front face of the case 20. In the present embodiment, for example, it is assumed that the plurality of LEDs 251 is configured to be capable of emitting light in a plurality of colors, including blue, yellow, and red. Note that the number of light emitting elements can be set arbitrarily, for example there may be one light emitting element in the light emitting unit 25.

The light-emitting unit 25 emits light in a predetermined light-emitting mode by a command from the MCU 1 to notify the user of predetermined information. Here, the light emitting mode can be, for example, a light emitting color, but this is not a limitation, for example it can be the intensity of the illumination (in other words luminance) or the illumination pattern (for example, blinking at a predetermined time interval), and so on. Also, the predetermined information is, for example, operational information indicating whether the inhalation device 100 is powered on or not.

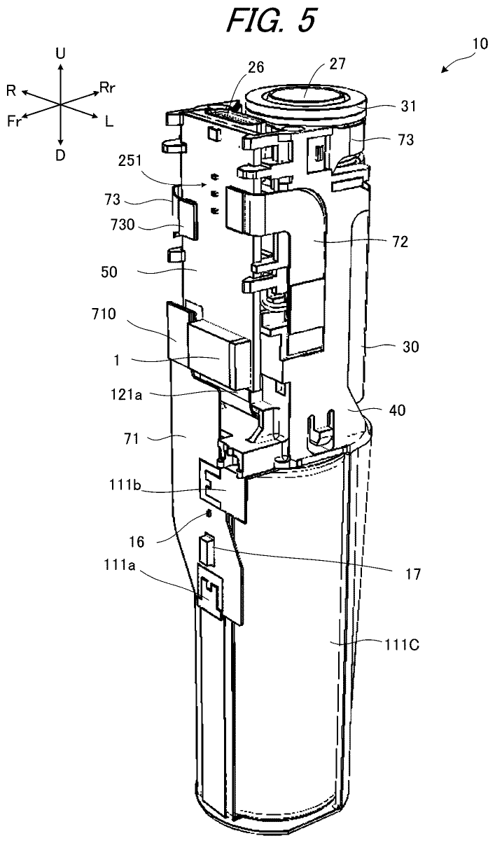

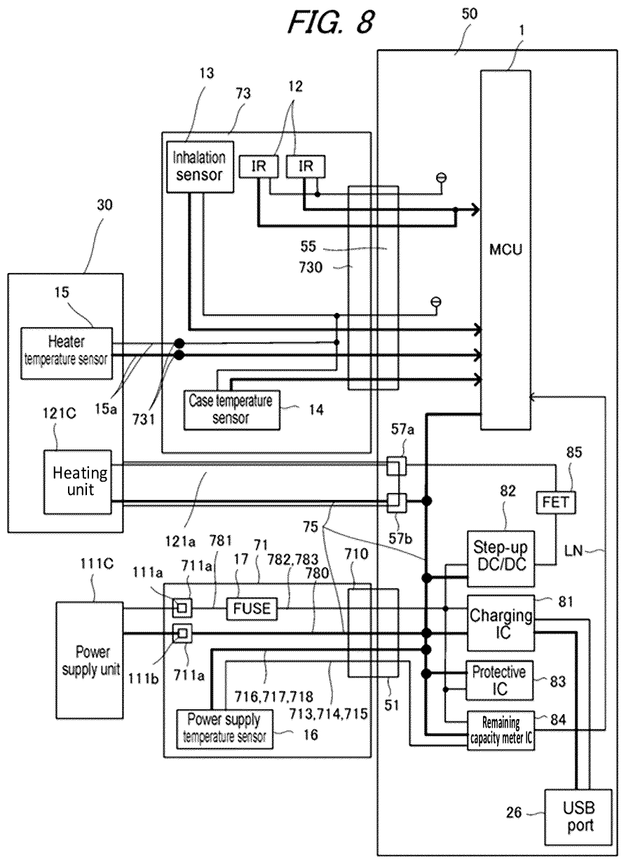

Next, the internal unit 10 of the inhalation device 100 of the present embodiment is described with reference to FIGS. 4 to 8. FIG. 4 is a perspective view seen from the front right side of an internal unit 10, FIG. 5 is a perspective view seen from the front left side of the internal unit 10, FIG. 6 is an exploded perspective view of the internal unit 10, FIG. 7 is a cross-sectional perspective view of a heater assembly 30, and FIG. 8 is a block diagram that briefly illustrates the electrical connection of the main elements of the internal unit 10. Note that the internal unit 10 is the inhalation device 100 from which the case 20 and the shutter 23 have been removed.

The internal unit 10 comprises a chassis 40, the main board 50, a vibration device 60, the heater assembly 30, the power supply part 111C, a power supply board 71, a peripheral FPC 72, a sensor FPC 73, and various sensors. The peripheral FPC 72 and the sensor FPC 73 are flexible circuit boards. The flexible circuit board is flexible and comprises conductive and/or signal wiring and can mount electronic components (elements) such as resistors and chips. The flexible circuit board is typically set in thickness to 100-600 μm. The power supply board 71 may be a flexible circuit board, a rigid board as described below, or a combination of a flexible board and a rigid board, but here the example of a flexible circuit board is described as an example.

### Chassis

The chassis 40 comprises, as shown in the exploded oblique view of FIG. 6, a power supply retention portion 41 holding the power supply part 111C, a board retention portion 42 holding the main board 50, and a heater retention portion 43 holding the heater assembly 30. The power supply retention portion 41 is located at the lower part of the chassis 40, and the board retention portion 42 and the heater retention portion 43 are located at the upper part of the chassis 40.

The power supply retention portion 41 has a cylindrical shape, with a portion of the side cut out, in other words a substantially semi-cylindrical shape. The power supply retention portion 41 has a bottom wall portion 401, a side wall portion 402 having a circular arc shape and standing upwards from the bottom wall portion 401, and a top wall portion 403 provided at the upper end of the side wall portion 402. The power supply part 111C is arranged in a space surrounded by the bottom wall portion 401, the side wall portion 402 and the top wall portion 403.

The board retention portion 42 is provided in a vertical wall portion 404 extending upward from the top wall portion 403 of the power supply retention portion 41. The board retention portion 42 is provided on one side (here on the front side) of the vertical wall portion 404 in the front-rear direction, and holds the main board 50.

The heater retention portion 43 is provided on the opposite side (here on the rear side) to the board retention portion 42 of the vertical wall portion 404 in the front-rear direction. The heater retention portion 43 has a space surrounded by the vertical wall portion 404, a left and right pair of wall portions 405 extending from the vertical wall portion 404 in a front-rear direction, and an upper surface of the top wall portion 403 of the power supply retaining portion 41, and the heater assembly 30 is arranged in this space.

### Main Board

The main board 50 is a rigid board with a plurality of electronic components (elements) mounted on both sides. The rigid board is not flexible and is generally set in thickness to 300-1,600 μm. On the main board 50, the MCU 1, the LED 251, a charging IC (integrated circuit) 81, a step-up DC/DC converter 82, and so on, are mounted. The main board 50 is held in the board retention portion 42 of the chassis 40 so that the element mounting surface is oriented in the front-rear direction. In FIG. 6, only a surface 501 of the main board 50 (here the front surface) is shown. Therefore, the charging IC 81 and the step-up DC/DC converter 82 mounted on the rear surface 502 (here on the back side), are not shown.

In the lower region of the surface 501 of the main board 50, a power connection part 51 is provided for electrical connection with the power supply part 111C. The power connection part 51 is electrically connected to the power supply part 111C via a board connection part 710 of the power supply board 71. The power supply part 111C is a cylindrical lithium-ion secondary battery, and is an example of the power supply part 111B of the inhalation device 100B of FIG. 2.

As shown in FIG. 6, the power supply part 111C is provided with a positive electrode tab 111a and a negative electrode tab 111b. The power supply part 111C is arranged in the power supply retention portion 41 of the chassis 40 so that the positive electrode tab 111a and the negative electrode tab 111b are arranged to the front. The power supply board 71 is arranged in front of the power supply part 111C and the main board 50, and extends in the vertical direction. With reference also to FIG. 8, a positive electrode tab connection part 711a and a negative electrode tab connection part 711b of the power supply board 71 are respectively connected to the positive electrode tab 111a and the negative electrode tab 111b of the power supply part 111C, and the board connection part 710 is electrically connected to the power connection part 51 of the main board 50. The power of the power supply part 111C is transmitted to the main board 50 through a conductive track formed in the power supply board 71, and is supplied to each electronic component, such as the step-up DC/DC converter 82. Also, the power supply board 71 is provided with a power supply temperature sensor 16. The power supply temperature sensor 16 is a sensor for measuring the temperature of the power supply part 111C. The power supply temperature sensor 16 is, for example, a thermistor. The power supply temperature sensor 16 is an example of the sensor unit 112B of the inhalation device 100B of FIG. 2.

The power supply board 71 is provided with a fuse 17 interposed in a conductive track formed in the power supply board 71. The fuse 17 breaks the circuit when an excessive current is flowing through it. The power supply board 71 will be described in more detail later.

A protective IC 83 and a remaining capacity meter IC 84 are further mounted on a surface 501 of the main board 50. Referring also to FIG. 8, the protective IC 83 seeks to protect the power supply portion 111C by stopping charging or discharging of the power supply part 111C in the event of overcharging or overdischarging of the power supply part 111C. The remaining capacity meter IC 84 derives battery information such as remaining capacity of the power supply part 111C, SOC (State of charge) indicating the state of charge, and SOH (State of Health) indicating the state of health, and obtains temperature information relating to the temperature of the power supply part 111C from the power supply temperature sensor 16. The remaining capacity meter IC 84 is connected to the MCU 1 by a communication line LN for serial communication and is configured to be able to communicate with the MCU 1.

The USB port 26 is provided in an upper region of the rear surface 502 of the main board 50. The USB port 26 is electrically connected to the charging IC 81 by wires formed in the main board 50.

Heater connections 57a, 57b are provided on the rear surface 502 of the main board 50, in addition to the charging IC 81 and the step-up DC/DC converter 82, as shown in FIG. 8. The charging IC 81 performs charging control to supply (charge) the power input from the USB port 26 to the power supply part 111C. The step-up DC/DC converter 82 steps up the voltage of the power supplied from the power supply part 111C, to generate power to supply to the heating unit 121C via a heating switch 85. The heating switch 85 is a FET (field effect transistor), for example.

A board connection part 121a extending from below the heater assembly 30 is connected to the heater connections 57a, 57b to provide power to the heating unit 121C of the heater assembly 30. In this way the heating unit 121C of the heater assembly 30 is supplied with power from the power supply part 111C via the main board 50.

### Vibration Device

The vibration device 60 is configured with a vibrating element such as, for example, a vibrating motor. As shown in FIG. 6, the vibration device 60 is arranged in the power supply retention portion 41 of the chassis 40 between the top surface of the power supply part 111C and the top wall portion 403. Lead wires 61 of the vibration device 60 are connected to the peripheral FPC 72. The vibration device 60 vibrates in a predetermined vibration mode by a command from the MCU 1, to notify the user of predetermined information. For example, at the start or end of heating of the stick-type substrate 150, the vibration device 60 vibrates in a predetermined vibration mode to notify the user of the start or end of heating. The vibration device 60 is an example of the notification unit 113B of the inhalation device 100B of FIG. 2.

### Heater Assembly

The heater assembly 30 comprises the heating unit 121C, the accommodating portion 140C, and the heat insulating portion 144C. The heating unit 121C is, for example, a film heater, and is wound around the outer circumference of the accommodating portion 140C. Also, the heating unit 121C and the board connection part 121a may be configured with a single heater FPC.

Also, the heater assembly 30 is provided with a stick guide 31. The stick guide 31 is provided at the top of the heater assembly 30, and guides the insertion and removal of the stick-type substrate 150 into the accommodating portion 140C. The stick guide 31 is a cylindrical-shaped member, has the opening 27, and constitutes part of the accommodating portion 140C.

Also, the heater assembly 30 is provided with a heater temperature sensor 15 capable of measuring the temperature of the heating unit 121C. More specifically, the heater temperature sensor 15 is provided between the heating unit 121C and the heat insulating portion 144C, in contact with or close to the heating unit 121C. The heater temperature sensor 15 is, for example, a thermistor.

### Sensor FPC

As shown in FIG. 6, the sensor FPC 73 is arranged in the heater retention portion 43 between the vertical wall portion 404 and the heater assembly 30. The sensor FPC 73 is equipped with a stick detection sensor 12, an inhalation sensor 13, and a case temperature sensor 14. The stick detection sensor 12, the inhalation sensor 13, and the case temperature sensor 14 are examples of the sensor unit 112B of the inhalation device 100B of FIG. 2.

The stick detection sensor 12 is a sensor capable of detecting the stick-type substrate 150 housed in the accommodating portion 140. In the present embodiment, the stick detection sensor 12 is an optical sensor capable of detecting the stick-type substrate 150 based on the amount of light reflected from the light emitted to the accommodating portion 140. Here, amount of light is a concept that includes luminous flux, illuminance, luminous emittance, brightness, luminance, and so on. The optical sensor is for example an infrared ray (IR) sensor.

The inhalation sensor 13 is a sensor that detects a puff action (inhalation action) of a user. The inhalation sensor 13 comprises, for example, a capacitor microphone, a pressure sensor, a puff thermistor, or the like. The inhalation sensor 13 is provided in proximity to the stick guide 31 in the sensor FPC 73.

The case temperature sensor 14 is a sensor for measuring the temperature of the case 20. The case temperature sensor 14 is, for example, a thermistor. The case temperature sensor 14 is arranged in the sensor FPC 73 next to the inner surface of the case 20.

Also, the sensor FPC 73 is provided with a heater temperature sensor connection part 731 connected to the heater temperature sensor 15 of the heater assembly 30. The heater temperature sensor connection part 731 is provided in the lower part of the sensor FPC 73. In more detail, lead wires 15a are connected to the heater temperature sensor 15, and the heater temperature sensor connection part 731 is connected to the lead wires 15a extending from underneath the heater assembly 30.

The stick detection sensor 12, the inhalation sensor 13, the case temperature sensor 14, and the heater temperature sensor connection part 731 are connected to a board connection part 730 via signal wiring formed in the sensor FPC 73. The board connection part 730 is connected to a sensor FPC connection part 55 provided in a central region of the surface 501 of the main board 50. In this way, the detection result of each sensor is output to the MCU 1, and so on, mounted on the main board 50.

In the inhalation device 100 configured in this way, when the open state of the shutter 23 is detected by the shutter detection sensor 11 and the stick-type substrate 150 is detected by the stick detection sensor 12, the MCU 1 starts the heating by the heating unit 121C. When a user inhales on the mouthpiece portion 152 of the stick-type substrate 150, aerosol is supplied into the user's mouth from the aerosol source of the stick-type substrate 150 heated by the heating unit 121C. The inhalation sensor 13 detects the number of puffs, and the MCU 1 stops the heating after a predetermined number of puffs or after a predetermined time has elapsed. During heating of the inhalation device 100, the case temperature sensor 14, the heater temperature sensor 15, and the power supply temperature sensor 16 measure each temperature, and if it is determined that there is abnormal heating, the MCU 1 stops or reduces the heating by the heating unit 121C. The user can also operate the operation unit 24 to, for example, check the SOC of the power supply part 111C, and so on. The light-emitting unit 25 (LED 251) and the vibration device 60 notify the user of various information such as the SOC of the power supply part 111C, error indications, and so on. When the SOC of the power supply part 111C drops, the user can connect an external power source to the USB port 26 to charge the power supply part 111C.

### Power Supply Board

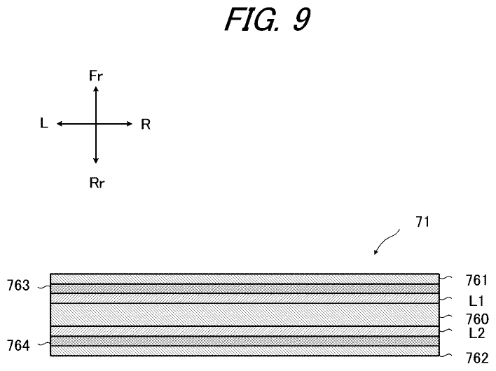

The power supply board 71 will then be described in detail with reference to FIG. 9-11.

FIG. 9 is a cross-sectional view of the power supply board 71. As shown in FIG. 9, the power supply board 71 has a multi-layer structure. Specifically, the power supply board 71 comprises a substrate 760, a first conductive layer L1 provided on one side of the substrate 760 (hereinafter the surface); a second conductive layer L2 provided on the other side of the substrate 760 (hereinafter the reverse surface); a first insulating layer 761 located on the first conductive layer L1; a second insulating layer 762 located on the second conductive layer L2; a first adhesive layer 763 adhering the first conductive layer L1 and the first insulating layer 761; and a second adhesive layer 764 adhering the second conductive layer L2 and the second insulating layer 762. The power supply board 71, when accommodated in the case 20 (hereinafter referred to as the accommodated state), is configured such that the lamination direction is in the front-rear direction, and arranged such that the first conductive layer L1 side faces forward, as shown FIG. 6.

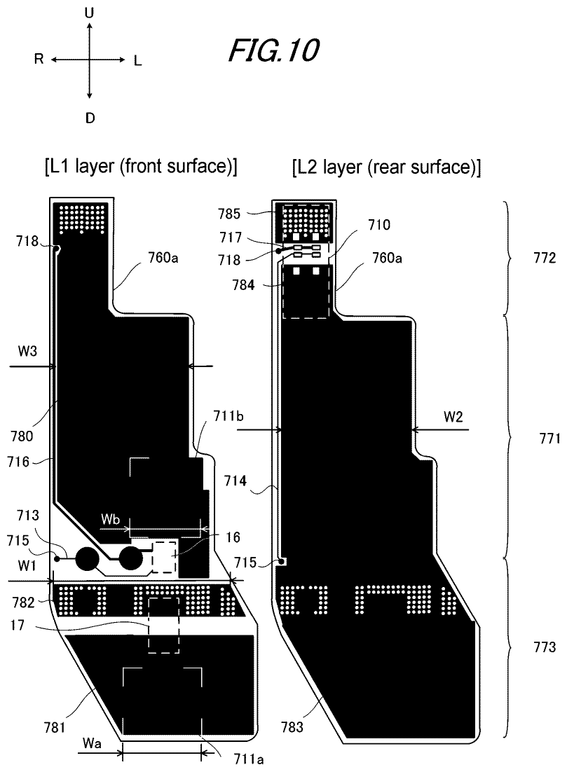

FIG. 10 is a view of the first conductive layer L1 and the second conductive layer L2 of the power supply board 71 seen from the front. In FIG. 10, the portion filled in black shows the electroconductive region and the line outside the electroconductive region shows the outer edge 760a of the substrate 760 of the power supply board 71 located between the first conductive layer L1 and the second conductive layer L2.

The power supply board 71 has a substantially rectangular body portion 771 which is longer in the vertical direction than the left-right direction, an upper right extension 772 which extends further upwards from the top right of the body portion 771, and a lower left extension 773 which extends tilting from the bottom of the body portion 771 towards the bottom left.

As noted above, the power supply board 71 is provided with a positive electrode tab connection part 711a and a negative electrode tab connection part 711b and is equipped with a power supply temperature sensor 16 and a fuse 17, which is electrically connected to the power supply connection part 51 of the main board 50 at the board connection part 710. More specifically, the positive electrode tab connection part 711a and the negative electrode tab connection part 711b are exposed to the surface of the power supply board 71. The power supply temperature sensor 16 and the fuse 17 are mounted on the surface of the power supply board 71 and connected to the first conductive layer L1 on the surface side shown in FIG. 10. The board connection part 710 is mounted on the reverse surface of the power supply board 71.

The first conductive layer L1 comprises a first negative electroconductive region 780 formed in the body portion 771 and the upper right extension 772, a first positive electroconductive region 781 formed in the lower part of the left lower extension 773, and a second positive electroconductive region 782 formed in the upper part of the left lower extension 773 and formed between the first negative electroconductive region 780 and the first positive electroconductive region 781. It should be noted that the first negative electroconductive region 780, the first positive electroconductive region 781, and the second positive electroconductive region 782 are spaced apart from each other in the vertical direction and isolated from each other. Furthermore, the first negative electroconductive region 780, the first positive electroconductive region 781, and the second positive electroconductive region 782 are formed slightly inwardly from an outer edge 760A in the width direction (left-right direction) over substantially the entire region.

The first positive electroconductive region 781 is provided with the positive electrode tab connection part 711a, and the first negative electroconductive region 780 is provided with the negative electrode tab connection part 711b. The positive electrode tab connection part 711a and the negative electrode tab connection part 711b are arranged at substantially the same position in the left-right direction and are arranged in close proximity with the second positive electroconductive region 782 sandwiched therebetween in the vertical direction.

The fuse 17 is connected between the first positive electroconductive region 781 and the second positive electroconductive region 782, and it is typically through this fuse 17 that the first positive electroconductive region 781 and the second positive electroconductive region 782 are conductive. On the other hand, in the event of overcurrent generation, the fuse 17 melts thereby isolating the first positive electroconductive region 781 and the second positive electroconductive region 782.

The second positive electroconductive region 782 is connected to the second conductive layer L2 via a plurality of through holes penetrating the substrate 760. The second conductive layer L2 has a third positive electroconductive region 783 formed across the main body portion 771 and the lower left extension 773, a positive contact connection part 784 formed at the bottom of the upper right extension 772 and connected to the positive contact of the board connection part 710, and a negative contact connection part 785 formed at the top of the upper right extension 772 and connected to the negative contact of the board connection part 710. The third positive electroconductive region 783 and the positive contact connection part 784 are continuous and always conductive. On the other hand, the positive contact connection part 784 and the negative contact connection part 785 are spaced apart from each other in the vertical direction and are isolated from each other.

In the power supply board 71 configured in this way, the power supplied from the positive electrode tab 111A of the power supply part 111C is supplied to the main board 50 through the positive electrode tab connection part 711a, the first positive electroconductive region 781, the fuse 17, the second positive electroconductive region 782, the third positive electroconductive region 783, the positive contact connection part 784, and the positive contact of the board connection part 710.

Also, the first negative electroconductive region 780 of the first conductive layer L1 is connected to the negative contact connection part 785 via a plurality of through holes through the substrate 760 and to the negative contact of the board connection part 710 mounted on the rear surface at the top of the upper right extension 772. Wiring connected from the negative electrode tab 111b of the power supply part 111C through the first negative electroconductive region 780 and the negative contact connection part 785 to the negative contact of the board connection part 710 is at the same potential as the reference electrical potential (ground potential) of the internal unit 10 and constitutes a ground line 75 (see FIG. 8).

Now, as shown in FIG. 10, the width W1 of the first positive electroconductive region 781 and the width W2 of the second positive electroconductive region 782 connecting the positive electrode tab connection part 711a and the positive contact connection part 784 are wider than the width Wa of the positive electrode tab connection part 711a. Note that width is the length in a direction orthogonal to the current flow direction In the present embodiment, the current flow direction is in the vertical direction from the positive electrode tab connection part 711a towards the positive contact connection part 784, and the width is the length in the left-right direction orthogonal to the vertical direction. Due to the wide width W1, W2 of the first positive electroconductive region 781 and the second positive electroconductive region 782, current concentration inside the power supply board 71 can be avoided even if a large current flows from the power supply part 111C through the positive electrode tab connection part 711a, and power can be supplied appropriately from the power supply part 111C. In particular, in the region where the positive electrode tab connection part 711a and the first positive electroconductive region 781 connect, it is preferred that the width W1 of the first positive electroconductive region 781 is wider than the width Wa of the positive electrode tab connection part 711a. Similarly, the width W3 of the first negative electroconductive region 780 connecting the negative electrode tab connection part 711b and the negative contact connection part 785 is wider than the width Wb of the negative electrode tab connection part 711b. In particular, in the region where the negative electrode tab connection part 711b and the first negative electroconductive region 780 connect, it is preferred that the width W3 of the first negative electroconductive region 780 is wider than the width Wb of the negative electrode tab connection part 711b.

In addition, the fuse 17 is provided between the first positive electroconductive region 781 and the second positive electroconductive region 782, and thus, if some type of abnormality causes current to flow from the power supply part 111C side to the main board 50 side or from the main board 50 side to the power supply part 111C side or above the rated current, it is possible to avoid the current continuing to flow by interrupting the circuit, thereby allowing power to be supplied safely. The main board 50 can also be reduced in size compared to arranging the fuse 17 in the main board 50.

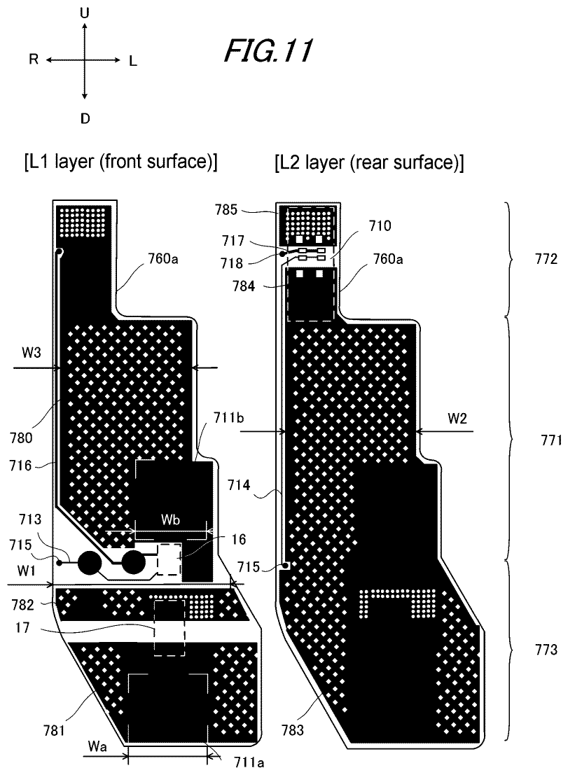

FIG. 11 is a view of the first conductive layer L1 and the second conductive layer L2 of the power supply board 71 of a variant example seen from the front. As shown in FIG. 11, the first positive electroconductive region 781, the second positive electroconductive region 782, the third positive electroconductive region 783, and the first negative electroconductive region 780 formed in the first conductive layer L1 and the second conductive layer L2 may be formed with electroconductive regions in a mesh shape. This can relieve the stress on the board connection part 710. On the other hand, at the first conductive layer L1 and the second conductive layer L2 of the power supply board 71 of FIG. 10, the DC current resistance is minimal and the power supply efficiency is good.

It should be noted that in the preceding embodiments, the power supply board 71 was equipped with the power supply temperature sensor 16 and the fuse 17, but is not limited to this, and other elements may be mounted. For example, from a safety point of view, the protective IC 83, a circuit-interrupting FET connected to the protective IC 83 to interrupt charging of the power supply part 111C or discharging to the power supply part 111C, and a current detection shunt resistor that is connected to the protective IC 83 and is for detecting charging or discharging of the power supply part 111C may be mounted. In particular, the protective IC 83 and the current detection shunt resistor not only improve safety, but also allow more accurate detection of the charging voltage and charging current or discharging voltage and discharging current of the power supply part 111C. That is, when the protective IC 83 is mounted on the power supply board 71, the voltage can be detected near the power supply part 111C compared to when mounted on the main board 50, and thus the accuracy of detection of overcharging, overdischarging, and short-circuiting caused by the voltage is improved. Mounting a protective IC 83 on the power supply board 71 can also allow these to be detected ahead of the fuse. Similarly, when the current detection shunt resistor is mounted on the power supply board 71, current can be detected near the power supply part 111C compared to when mounted on the main board 50, and thus the accuracy of detection of overcharging, overdischarging, and short-circuiting caused by the current is improved. Mounting the current detection shunt resistor on the power supply board 71 can also allow these to be detected ahead of the fuse 17.

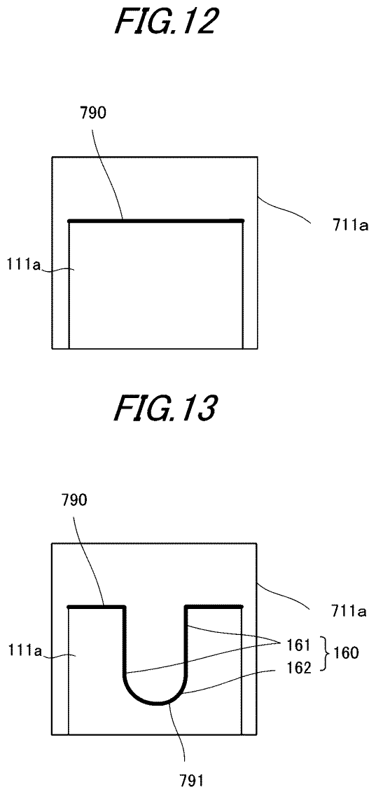

FIGS. 12 and 13 are a diagram illustrating another example of the positive electrode tab 111a connected to the positive electrode tab connection part 711a. Note that, although the description thereof is omitted, the same also applies to the negative electrode tab 111b which is connected to the negative electrode tab connection part 711b.

The connection between the positive electrode tab 111a and the positive electrode tab connection part 711a is generally performed by soldering the tip of the positive electrode tab 111a to the positive electrode tab connection part 711a. FIG. 12 shows a rectangular positive electrode tab 111a soldered to the rectangular positive electrode tab connection part 711a, and a connecting line 790 where the positive electrode tab 111a and the positive electrode tab connection part 711a are connected by the soldering is straight.

As shown in FIG. 13, when the rectangular positive electrode tab 111a formed with a recess 160 is soldered to the rectangular positive electrode tab connection part 711a, a recess 791 is formed in the connecting line 790. If the recess 160 is configured by connecting one end of two parallel straight portions 161 together by a semi-arc 162, the bottom portion of the recess 791 includes a semi-arc. Note that the bottom portion of the recess 791 may include an arc of ellipse. In this way, the connecting line 790 includes the recess 791, thereby making the connecting line 790 longer than a simple straight line, and therefore resistance decreases and the power supply efficiency can be raised. Furthermore, by rendering the bottom of the recess 791 as an arc, current concentrating at the corners can be avoided, and the power supply efficiency can be raised further.

The connecting line 790 is not limited to including a recess, and may include a protrusion, or any configuration as long as at least a portion includes a curved section or bent section such as a zig-zag type or wave type. It should be noted that the present disclosure does not exclude that the connecting line 790 is a simple straight line.

Returning to FIGS. 4 to 6, the power supply temperature sensor 16 mounted on a surface of the power supply board 71 is provided between the positive electrode tab connection part 711a and the negative electrode tab connection part 711b together with the fuse 17. As shown in FIG. 10, the power supply temperature sensor 16 is located in a space between the first positive electroconductive region 781 and the second positive electroconductive region 782 of the first conductive layer L1 provided for short-circuit prevention and is connected to the board connection part 710. By mounting the power supply temperature sensor 16 on the power supply board 71, the connection of the power supply part 111C to the main board 50 and the connection of the power supply temperature sensor 16 to the main board 50 can be made common, and the main board 50 can be reduced in size.

More specifically, as shown in FIG. 10, the positive terminal of the power supply temperature sensor 16 connects to a positive signal contact of the board connection part 710 via a first positive signal wire 713 formed in the first conductive layer L1, a second positive signal wire 714 formed in the second conductive layer L2, and a through hole 715 connecting the first positive signal wire 713 and the second positive signal wire 714. The positive signal contact of the board connection part 710 is connected to the positive signal contact of the main board 50. The negative terminal of the power supply temperature sensor 16 connects to a negative signal contact of the board connection part 710 via a first negative signal wire 716 formed in the first conductive layer L1, a second negative signal wire 717 formed in the second conductive layer L2, and a through hole 718 connecting the first negative signal wire 716 and the second negative signal wire 717. The negative signal contact of the board connection part 710 is connected to the negative signal contact of the main board 50.

Here, the second positive signal wire 714 extends in the vertical direction between the third positive electroconductive region 783 formed in the second conductive layer L2 and the outer edge 760a at the right end of the substrate 760. Providing the second positive signal wire 714 in the middle of the third positive electroconductive region 783 narrows the third positive electroconductive region 783 and generates current concentration, but providing the second positive signal wire 714 between the outer edge 760a and the third positive electroconductive region 783 of the power supply board 71 can ensure a wide third positive electroconductive region 783.

Similarly, the first negative signal wire 716 extends in the vertical direction between the first negative electroconductive region 780 formed in the first conductive layer L1 and the outer edge 760a at the right end of the substrate 760. By providing the first negative signal wire 716 between the outer edge 760a of the power supply board 71 and the first negative electroconductive region 780, a wide first negative electroconductive region 780 can be ensured.

By providing the second positive signal wire 714 and the first negative signal wire 716 having long wiring distances in different layers, a wider electroconductive region can be ensured than if provided in the same layer. Furthermore, the second positive signal wire 714 and the first negative signal wiring 716 are arranged to overlap when viewed from the lamination direction.

As shown in FIGS. 4 to 6, the surface of the power supply board 71 on which the power supply temperature sensor 16 and the fuse 17 are mounted is located opposite to the surface facing the power supply part 111C. This avoids damage to the power supply temperature sensor 16 and the fuse 17 upon attaching and detaching of the power supply part 111C.

Although various embodiments of the present disclosure have been described above with reference to the drawings, it goes without saying that the present disclosure is not limited to such examples. It is obvious that a person skilled in the art will be able to conceive of a number of variant examples or modified examples within the scope disclosed in the claims, and any such variant examples or modified examples are naturally understood to fall within the technical scope of the present disclosure. Furthermore, the components in the embodiment described above may be arbitrarily combined within a range not deviating from the spirit of the invention.

For example, the power supply board 71 had two layers of conductive layers L1, L2, but the conductive layer may be one layer or may be three or more layers.

The present specification sets forth at least the following features. Note that corresponding components and so on in the embodiment described above are shown in parentheses, but are not limited thereto.
(1) A power supply unit (power supply unit 110, inhalation device 100B, 100) for an aerosol-generating device, the power supply unit comprising: a power supply (power supply part 111A to 111C) that supplies power to a heating unit (heating unit 121A to 121C) for heating an aerosol source (stick-type substrate 150);
a control device (control unit 116A, control unit 116B, MCU 1) that controls the heating unit;
a first board (main board 50) for mounting the control device; and
a second board (power supply board 71) connected to the power supply and the first board, wherein
the second board includes
   an electrode connection part (positive electrode tab connection part 711a, negative electrode tab connection part 711b) connected to an electrode (positive electrode tab 111a) of the power supply,
   a contact connection part (positive contact connection part 784) connected to a contact of the first board, and
   an electroconductive region (first positive electroconductive region 781, second positive electroconductive region 782) connecting the electrode connection part and the contact connection part, and
the width (width W1, width W2) of the electroconductive region is wider than the width (width Wa) of the electrode connection part.

According to (1), due to the wide conductive region, current concentration within the second board can be avoided even if a large current flows from the power supply via the electrode connection, and power can be suitably supplied from the power supply.
(2) The power supply unit for an aerosol-generating device according to (1), wherein
a fuse (fuse 17) is mounted on the second board in the electroconductive region.

According to (2), if any abnormality causes current equal to or greater than the rated current to flow from the power supply side to the first board side or from the first board side to the power supply side, it is possible to avoid the current continuing to flow by interrupting the circuit, thereby allowing power to be supplied safely. Furthermore, the first board can also be reduced in size compared to arranging the fuse in the first board.
(3) The power supply unit for an aerosol-generating device according to (1) or (2), wherein
an electrode tab (positive electrode tab 111a) extending from the power supply is connected to the electrode connection part,
at least a portion of an outer edge of the electrode tab is connected to the electrode connection part, and
a connecting line (connecting line 790) of the electrode tab and the electrode connection part includes a bent section or a curved section.

According to (3), when the electrode tab and the electrode connection part are connected such as by soldering to form a connecting line, the connecting line is longer than a simple straight line, and thus resistance decreases and the power supply efficiency can be raised.
(4) The power supply unit for an aerosol-generating device according to (3), wherein
the connecting line includes a recess (recess 791).

According to (4), a longer connecting line can be ensured.
(5) The power supply unit for an aerosol-generating device according to (4), wherein
a bottom portion of the recess is an arc of a circle or ellipse.

According to (5), current concentrating at the corners can be avoided, and the power supply efficiency can be raised further.
(6) The power supply unit for an aerosol-generating device according to any one of (1) to (5), wherein
a thermistor (power supply temperature sensor 16) is mounted on the second board.

According to (6), the connection of the power supply to the first board and the connection of the thermistor to the first board can be made common, and the first board can be reduced in size. Furthermore, the first board can also be reduced in size compared to arranging the thermistor in the main board.
(7) The power supply unit for an aerosol-generating device according to (6), wherein
the thermistor is connected to the first board via a signal wire (first positive signal wire 713, second positive signal wire 714, first negative signal wire 716, second negative signal wire 717), and
at least a portion (second positive signal wire 714, first negative signal wire 716) of the signal wire is provided between an outer edge (outer edge 760a) of the second board and the electroconductive region.

According to (7), when the signal wire is passed between the electroconductive regions, the electroconductive region is narrowed and current concentration is generated, but by providing the signal wire between the outer edge of the second board and the conductive region, a wide electroconductive region can be ensured.
(8) The power supply unit for an aerosol-generating device according to (6) or (7), wherein
the thermistor is connected to a connection part (power supply connection part 51) of the first board via a positive signal wire (second positive signal wire 714) and a negative signal wire (first negative signal wire 716),
the second board includes
a multilayer structure,
at least a portion of the negative signal wire is disposed in a first layer (first conductive layer L1), and
at least a portion of the positive signal wire is disposed in a second layer (second conductive layer), which is a layer different than the first layer.

According to (8), by providing two signal wires in different layers, a wider electroconductive region can be ensured than if provided in the same layer.
(9) The power supply unit for an aerosol-generating device according to (8), wherein
the positive signal wire and the negative signal wire are disposed so as to overlap as viewed from a lamination direction.

According to (9), the positions of the signal wires can be integrated.
(10) The power supply unit for an aerosol-generating device according to any one of (6) to (9), wherein
the electrode connection part has a positive electrode connection part (positive electrode tab connection part 711a) and a negative electrode connection part (negative electrode tab connection part 711b), and
the thermistor is disposed between the positive electrode connection part and the negative electrode connection part.

According to (10), the second board can be reduced in size by arranging the thermistor in the space provided for short-circuit prevention.
(11) The power supply unit for an aerosol-generating device according to (2), wherein
the electrode connection part has a positive electrode connection part (positive electrode tab connection part 711a) and a negative electrode connection part (negative electrode tab connection part 711b), and
the fuse is disposed between the positive electrode connection part and the negative electrode connection part.

According to (11), the second board can be reduced in size by arranging the fuse in the space provided for short-circuit prevention.
(12) The power supply unit for an aerosol-generating device according to (10), wherein
a fuse (fuse 17) is mounted on the second board in the electroconductive region, and
the thermistor and the fuse are disposed between the positive electrode connection part and the negative electrode connection part.

According to (12), the second board can be reduced in size by arranging the thermistor and fuse in the space provided for short-circuit prevention.
(13) The power supply unit for an aerosol-generating device according to (12), wherein
the thermistor and the fuse are mounted on a surface (front surface) on the opposite side of the power supply.

According to (13), damage to the thermistor and the fuse can be avoided upon attaching and detaching the power supply.
(14) The power supply unit for an aerosol-generating device according to any one of (1) to (13), wherein
the first board is a rigid board and the second board is a flexible circuit board.

According to (14), power concentration inside the flexible circuit board can be avoided and power can be appropriately supplied from the power source.
(15) An aerosol-generating device (inhalation device 100B, 100) comprising: a power supply (power supply part 111A to 111C);
a heating unit (heating unit 121A to 121C) that consumes electrical power supplied from the power supply to heat an aerosol source;
a control device (control unit 116A, control unit 116B, MUC 1) that controls the heating unit;
a first board (main board 50) for mounting the control device; and
a second board (power supply board 71) connected to the power supply and the first board, wherein
the second board includes
   an electrode connection part (positive electrode tab connection part 711a) connected to an electrode of the power supply,
   a contact connection part (positive contact connection part 784) connected to a contact of the first board, and
   an electroconductive region (first positive electroconductive region 781, second positive electroconductive region 782) connecting the electrode connection part and the contact connection part, and
the width (width W1, width W2) of the electroconductive region is wider than the width (width Wa) of the electrode connection part.

According to (15), due to the wide electroconductive region, current concentration within the second board can be avoided even if a large current flows from the power supply via the electrode connection, and power can be suitably supplied from the power supply.

### REFERENCE SIGNS LIST

16 Power supply temperature sensor (thermistor)
17 Fuse
50 Main board (first board)
51 Power supply connection part (connection part of first board)
71 Power supply board (second board)
100A Inhalation device (aerosol-generating device)
100 Inhalation device (aerosol-generating device, power supply unit)
100B Inhalation device (aerosol-generating device, power supply unit)
110 Power supply unit
111A Power supply part (power supply)
111B Power supply part (power supply)
111C Power supply part (power supply)
111a Positive electrode tab (electrode, electrode tab)
116A Control unit (control device)
116B Control unit (control device)
121A Heating unit
121B Heating unit
121C Heating unit
150 Stick-type substrate (aerosol source)
711a Positive electrode tab connection part (electrode connection part, positive electrode connection part)
711b Negative electrode tab connection part (electrode connection part, negative electrode connection part)
713 First positive signal wire (signal wire)
714 Second positive signal wire (signal wire)
716 First negative signal wire (signal wire)
717 Second negative signal wire (signal wire)
781 First positive electroconductive region (electroconductive region)
782 Second positive electroconductive region (electroconductive region)
784 Positive contact connection part (contact connection part)
790 Connecting line
791 Recess
L1 First conductive layer (first layer)
L2 Second conductive layer (second layer)
W1 Width of first positive electroconductive region (width of electroconductive region)
W2 Width of second positive electroconductive region (width of electroconductive region)
Wa Width of the positive electrode tab connection part (width of electrode connection part)
MCU 1 (control device)

1-15. (canceled)

16. A power supply unit for an aerosol-generating device, the power supply unit comprising:
a power source that supplies electrical power to a heater that heats an aerosol source;
circuitry that controls the heater;
a first board on which the circuitry is mounted; and
a second board connected to the power source and the first board, wherein
the second board comprises:
an electrode connection part connected to an electrode of the power source,
a contact connection part connected to a contact of the first board, and
an electroconductive region connecting the electrode connection part and the contact connection part, and
a width of the electroconductive region is greater than a width of the electrode connection part.

17. The power supply unit of claim 16, wherein a fuse is mounted on the second board in the electroconductive region.

18. The power supply unit of claim 16, wherein:
an electrode tab extending from the power source is connected to the electrode connection part,
at least a portion of an outer edge of the electrode tab is connected to the electrode connection part, and
a connecting line where the electrode tab and the electrode connection part are connected includes a bent section or a curved section.

19. The power supply unit of claim 18, wherein the connecting line includes a recess.

20. The power supply unit of claim 19, wherein a bottom portion of the recess is an arc of a circle or an arc of an ellipse.

21. The power supply unit of claim 16, wherein a thermistor is mounted on the second board.

22. The power supply unit of claim 21, wherein:
the thermistor is connected to the first board via a signal wire, and
at least a portion of the signal wire is provided between an outer edge of the second board and the electroconductive region.

23. The power supply unit of claim 21, wherein:
the thermistor is connected to a connection part of the first board via a positive signal wire and a negative signal wire,
the second board has a multilayer structure,
at least a portion of the negative signal wire is disposed in a first layer of the multilayer structure, and
at least a portion of the positive signal wire is disposed in a second layer of the multilayer structure that is different from the first layer.

24. The power supply unit of claim 23, wherein the positive signal wire and the negative signal wire are arranged to overlap as viewed from a lamination direction of the multilayer structure.

25. The power supply unit of claim 21, wherein:
the electrode connection part comprises a positive electrode connection part and a negative electrode connection part, and
the thermistor is disposed between the positive electrode connection part and the negative electrode connection part.

26. The power supply unit of claim 17, wherein:
the electrode connection part comprises a positive electrode connection part and a negative electrode connection part, and
the fuse is disposed between the positive electrode connection part and the negative electrode connection part.

27. The power supply unit of claim 25, further comprising a fuse mounted on the second board in the electroconductive region, wherein the thermistor and the fuse are disposed between the positive electrode connection part and the negative electrode connection part.

28. The power supply unit of claim 27, wherein the thermistor and the fuse are mounted on a surface of the second board that is on an opposite side from the power source.

29. The power supply unit of claim 16, wherein the first board is a rigid board and the second board is a flexible circuit board.

30. The power supply unit of claim 16, wherein the power source comprises a rechargeable battery.

31. The power supply unit of claim 16, wherein the electroconductive region has a mesh shape.

32. The power supply unit of claim 17, wherein:
the electroconductive region comprises a first electroconductive region connected to the electrode connection part and a second electroconductive region connected to the contact connection part, and
the fuse is connected between the first electroconductive region and the second electroconductive region.

33. The power supply unit of claim 16, wherein the second board has a multilayer structure comprising a first conductive layer and a second conductive layer on opposite sides of a substrate, and the electroconductive region is formed in at least one of the first conductive layer and the second conductive layer.

34. A power supply unit for an aerosol-generating device, the power supply unit comprising:
a rechargeable battery having a positive electrode tab and a negative electrode tab;
a heater that heats an aerosol source using electrical power supplied from the rechargeable battery;
circuitry that controls the heater;
a first board on which the circuitry is mounted; and
a flexible circuit board having a multilayer structure and connected between the rechargeable battery and the first board, the flexible circuit board comprising:
a positive electrode connection part connected to the positive electrode tab,
a negative electrode connection part connected to the negative electrode tab,
a contact connection part connected to a contact of the first board,
a first electroconductive region connected to the positive electrode connection part,
a second electroconductive region connected to the contact connection part,
a fuse connected between the first electroconductive region and the second electroconductive region, and
a thermistor mounted on the flexible circuit board and configured to measure a temperature of the rechargeable battery, wherein
the thermistor and the fuse are disposed between the positive electrode connection part and the negative electrode connection part, and
a width of the first electroconductive region and a width of the second electroconductive region are each greater than a width of the positive electrode connection part.

35. An aerosol-generating device comprising:
a power source;
a heater that heats an aerosol source using electrical power supplied from the power source;
circuitry that controls the heater;
a first board on which the circuitry is mounted; and
a second board connected to the power source and the first board, wherein
the second board comprises:
an electrode connection part connected to an electrode of the power source,
a contact connection part connected to a contact of the first board, and
an electroconductive region connecting the electrode connection part and the contact connection part, and
a width of the electroconductive region is greater than a width of the electrode connection part.
